(19) United States
(12) Patent Application Publication
(10) Pub. No.: US 2025/0160048 A1
(43) Pub. Date: May 15, 2025

(54) INFRARED DETECTOR, METHOD OF MANUFACTURING THE SAME, AND OPTICAL INTERCONNECTION STRUCTURE INCLUDING THE INFRARED DETECTOR

(71) Applicant: SAMSUNG ELECTRONICS CO., LTD., Suwon-si (KR)

(72) Inventor: Youngzoon YOON, Suwon-si (KR)

(73) Assignee: SAMSUNG ELECTRONICS CO., LTD., Suwon-si (KR)

(21) Appl. No.: 18/949,016

(22) Filed: Nov. 15, 2024

(30) Foreign Application Priority Data
Nov. 15, 2023 (KR) 10-2023-0158625

(51) Int. Cl. H01L 31/0224; H01L 31/0232; H01L 31/103

(52) U.S. Cl. CPC H10F 77/206; H10F 30/221; H10F 77/413

(57) ABSTRACT

An infrared detector, a manufacturing method thereof, and an optical interconnection structure including an infrared detector are provided. The infrared detector according to an embodiment includes an infrared absorption layer that is in contact with a substrate and is provided to absorb short-wavelength infrared rays and first and second electrode layers connected to the infrared absorption layer and spaced apart from each other. The infrared absorption layer includes a metal nanostructure embedded in the center of the infrared absorption layer and positioned to correspond to a mode period of incident light. A light reflection layer may be further provided at an end portion of the infrared absorption layer.

### CROSS-REFERENCE TO RELATED APPLICATION

This application is based on and claims priority under 35 U.S.C. § 119 to Korean Patent Application No. 10-2023-0158625, filed on Nov. 15, 2023, in the Korean Intellectual Property Office, the disclosure of which is incorporated by reference herein in its entirety.

### BACKGROUND

### 1. Field

One or more example embodiments of the disclosure relate to a photodetector, a method of manufacturing the same, and an application of the photodetector, and more particularly, to an infrared detector, a method of manufacturing the same, and an optical interconnection structure including the infrared detector.

### 2. Description of the Related Art

A method of detecting a signal mode transmitted through an optical waveguide with an optical detector may be divided into a vertical optical coupling through optical fiber transmission and a lateral optical coupling through an optical waveguide. The lateral optical coupling method may further be divided into Evanescent coupling and Butt coupling.

A length and a width of a light detection layer in a light detector may be major factors affecting the high-speed operation of the light detector, and as the size of the light detection layer becomes smaller, the high-speed operation characteristics may be improved. Additionally, as the size of the light detection layer decreases, dark current may decrease, but a light absorption rate may decrease.

### SUMMARY

One or more example embodiments of the disclosure may provide a photodetector capable of operating at a high speed.

Further, one or more example embodiments of the disclosure may provide a photodetector capable of increasing a light absorption rate.

Further, one or more example embodiments of the disclosure may provide a photodetector capable of increasing an integration degree.

Further, one or more example embodiments of the disclosure may provide a method of manufacturing a photodetector.

Still further, one or more example embodiments may provide an optical interconnection structure including the photodetector.

Additional aspects will be set forth in part in the description which follows and, in part, will be apparent from the description, or may be learned by practice of the presented embodiments of the disclosure.

According to an aspect of an example embodiment of the disclosure, provided is an infrared detector including: a substrate; an infrared absorption layer in contact with the substrate and provided to absorb short-wavelength infrared rays; and a first electrode layer and a second electrode layer connected to the infrared absorption layer and spaced apart from each other, wherein the infrared absorption layer includes a metal nanostructure embedded in a center of the infrared absorption layer and positioned to correspond to a mode period of incident light.

The substrate may include a first doped layer and a second doped layer spaced apart from each other and facing each other with the infrared absorption layer therebetween, and the first electrode layer may be connected to the first doped layer, the second electrode layer is connected to the second doped layer, and the first doped layer and the second doped layer are in contact with the infrared absorption layer.

The infrared detector may further include a third electrode layer provided between the first electrode layer and the second electrode layer, wherein the third electrode layer is spaced apart from the first electrode layer, the second electrode layer, and the infrared absorption layer.

The first doped layer and the second doped layer may include regions doped with an n-type impurity.

In each of the first doped layer and the second doped layer, a doping concentration may increase in a direction away from the infrared absorption layer.

The infrared detector may further include a third electrode layer provided between the first electrode layer and the second electrode layer, wherein the third electrode layer is spaced apart from the first electrode layer, the second electrode layer, and the infrared absorption layer, and the first electrode layer and the second electrode layer may be in direct contact with the infrared absorption layer.

The infrared absorption layer may extend on or below the first electrode layer and the second electrode layer.

One of the first doped layer and the second doped layer may include a region doped with a p-type impurity, and the other of the first doped layer and the second doped layer may include a region doped with an n-type impurity.

The metal nanostructure may include a plurality of metal nanopatterns arranged in one row, two rows, or three rows in a longitudinal direction of the infrared absorption layer.

The plurality of metal nanopatterns may be aligned to have a pitch corresponding to the mode period of incident light.

The infrared absorption layer may have a layer structure in which a crystalline layer and an amorphous layer are sequentially stacked.

A length of the infrared absorption layer may be 1 μm or less, and a width in a direction perpendicular to a length direction of the infrared absorption layer may be 100 nm or less.

The infrared detector may further include a light reflection layer provided at an end portion of the infrared absorption layer.

The infrared absorption layer may include one of a germanium (Ge) layer and a quantum dot layer.

According to an aspect of an example embodiment of the disclosure, provided is an optical interconnection structure including: a waveguide; and an infrared detector connected to the waveguide, wherein the infrared detector includes: an infrared absorption layer in contact with the waveguide and provided to absorb short-wavelength infrared rays; and a first electrode layer and a second electrode layer connected to the infrared absorption layer and spaced apart from each other, and wherein the infrared absorption layer includes: a metal nanostructure embedded in a center of the infrared absorption layer and positioned to correspond to a mode period of incident light transmitted through the waveguide; and a light reflection layer provided at an end portion of the infrared absorption layer.

The waveguide may include a groove, and the infrared absorption layer may be provided to fill the groove.

The infrared absorption layer may be provided on an upper surface of the waveguide.

The waveguide may include a first doped layer and a second doped layer that are provided to face each other with the infrared absorption layer therebetween, the first doped layer and the second doped layer being spaced apart from each other, and wherein the first electrode layer is connected to the infrared absorption layer through the first doped layer, and the second electrode layer is connected to the infrared absorption layer through the second doped layer.

According to an aspect of an example embodiment of the disclosure, provided is a method of manufacturing an infrared detector, the method including: forming a first infrared absorption layer by using an epitaxy method in a region of a substrate; forming a metal nanostructure on the first infrared absorption layer; forming a second infrared absorption layer on the first infrared absorption layer to completely cover the metal nanostructure; and forming a first electrode layer and a second electrode layer to be connected to at least the second infrared absorption layer, wherein the metal nanostructure is positioned corresponding to a mode period of incident light, and wherein the second infrared absorption layer is formed by using a non-growth method.

The first electrode layer and the second electrode layer may be formed to directly contact the second infrared absorption layer, and a third electrode layer may be formed between the first electrode layer and the second electrode layer to be spaced apart from the first infrared absorption layer and the second infrared absorption layer.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The above and other aspects will be more apparent by describing certain example embodiments, with reference to the accompanying drawings, in which:

FIG. 1, FIG. 2, FIG. 3, and FIG. 4 are cross-sectional views showing first photodetectors according to one or more example embodiments;

FIG. 5 and FIG. 6 are cross-sectional views showing a second photodetector according to one or more example embodiments;

FIG. 7 is a plan view of the first photodetector of FIG. 1 and the second photodetector of FIG. 5;

FIG. 8 is a plan view of the first photodetector of FIG. 2 and the second photodetector of FIG. 6;

FIG. 9 is a plan view showing a case in which a first photodetector is coupled to a waveguide as a mechanism (system) for optical interconnection according to an embodiment;

FIG. 10 is a cross-sectional view taken along line 10-10′ of FIG. 9;

FIG. 11 is a cross-sectional view showing a case where a light absorption layer is provided on an upper surface of the waveguide in FIG. 10;

FIG. 12A and FIG. 12B show images showing an electric field distribution in a light absorption layer when light with a wavelength of 1310 nm is incident on first to third samples in a simulation conducted to examine optical characteristics when a first photodetector is coupled to a waveguide as an optical interconnection structure according to one or more example embodiments;

FIG. 13 is a graph showing a relationship between the light absorption rate and wavelength for first to third samples when light with a wavelength of 1310 nm is incident on first to third samples in a simulation conducted to examine optical characteristics when a first photodetector is coupled to a waveguide as an optical interconnection structure according to an embodiment; and

FIG. 14, FIG. 15, FIG. 16, FIG. 17A, FIG. 17B, FIG. 18, FIG. 19, FIG. 20, FIG. 21, FIG. 22, FIG. 23, and FIG. 24 are drawings (cross-sectional views or plan views) showing step-by-step a method of manufacturing a photodetector according to one or more example embodiments.

### DETAILED DESCRIPTION

Example embodiments are described in greater detail below with reference to the accompanying drawings. In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

As used herein, the term “and/or” includes any and all combinations of one or more of the associated listed items. Expressions such as “at least one of,” when preceding a list of elements, modify the entire list of elements and do not modify the individual elements of the list. While such terms as “first,” “second,” etc., may be used to describe various elements, such elements must not be limited to the above terms. The above terms may be used only to distinguish one element from another.

Hereinafter, an infrared detector, a manufacturing method thereof, and an optical interconnection structure including the infrared detector according to embodiments will be described in detail with reference to the accompanying drawings. In this process, thicknesses of layers or regions shown in the drawings may be somewhat exaggerated for clarity of the specification.

The embodiments of the disclosure are capable of various modifications and may be embodied in many different forms. In a layer structure described below, when a position of an element is described using an expression “above” or “on”, the position of the element may include not only the element being “immediately in a contact manner” but also being in a non-contact manner”. In the description below, like reference numerals in the drawings refer to like elements throughout,

The singular forms include the plural forms unless the context clearly indicates otherwise. When a portion “includes” a constituent element, another element may be further included, rather than excluding the existence of the other element, unless otherwise described.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the terms “units” or “ . . . modules” denote units or modules that process at least one function or operation, and may be realized by hardware, software, or a combination of hardware and software.

Connections or connection members of lines between components shown in the drawings illustrate functional connections and/or physical or circuit connections, and the connections or connection members may be represented by replaceable or additional various functional connections, physical connections, or circuit connections in an actual apparatus.

All examples or example terms are simply used to explain in detail the technical scope of the disclosure, and thus, the scope of the disclosure is not limited by the examples or the example terms as long as it is not defined by the claims.

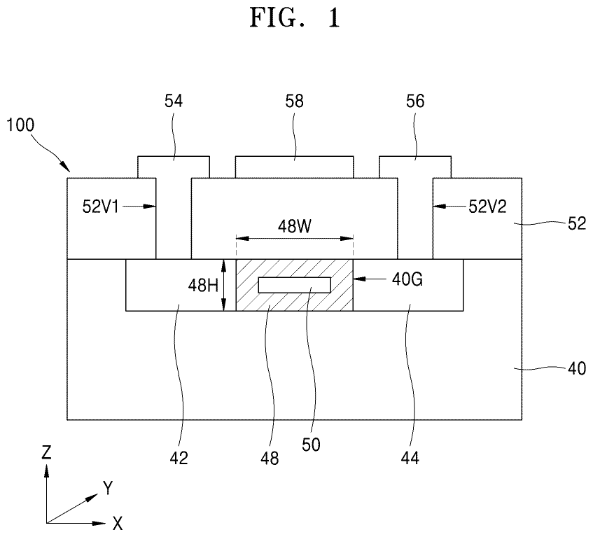

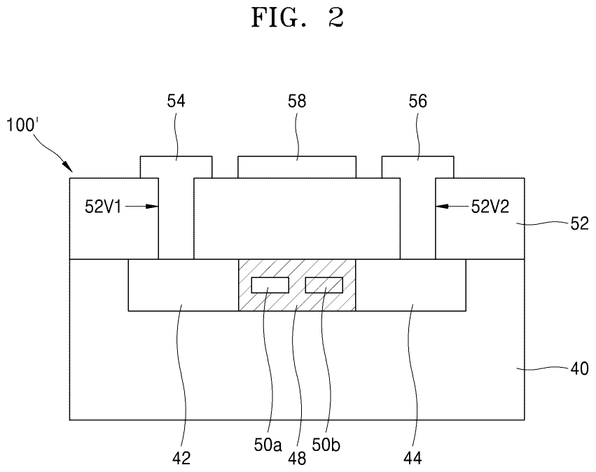

FIGS. 1-4 are cross-sectional views showing first photodetectors according to one or more example embodiments. FIG. 1 shows a first photodetector 100 according to an example embodiment. The first photodetector 100 in FIG. 1 may also be expressed as a photodetection device.

Referring to FIG. 1, the first photodetector 100 includes a substrate 40 including a first doped layer 42 and a second doped layer 44, and a light absorption layer 48 provided in the substrate 40 between the first doped layer 42 and the second doped layer 44. In one example, the substrate 40 may be a silicon (Si) substrate or may include a silicon substrate, but is not limited thereto. The light absorption layer 48 may be provided to have the same height as the first and second doped layers 42 and 44. In one example, the light absorption layer 48 may be a layer provided to absorb light in an infrared band. As an example, the light absorption layer 48 may include an absorption layer provided to absorb light in an infrared band used in optical communication. For example, the light absorption layer 48 may include a material layer prepared to absorb light with a wavelength in a range from about 1200 nm to about 1600 nm. In one example, the light absorption layer 48 may be a layer including germanium (Ge) or may include a germanium layer. In one example, the light absorption layer 48 may be a quantum dot layer including quantum dots (QDs) having a size capable of absorbing wavelengths in the infrared band or may include such a quantum dot layer. In one example, the light absorption layer 48 may include two crystalline states. For example, a portion of the light absorption layer 48 may be crystalline and the remainder of the light absorption layer 48 may be amorphous. For example, a portion below a nanostructure 50 of the light absorption layer 48 may be crystalline and the remainder of the light absorption layer 48 may be amorphous. In one example, a width 48W of the light absorption layer 48 may be designed to be less than a width of an apparatus or a member on which the first photodetector 100 will be mounted. As an example, when the first photodetector 100 is coupled to, mounted on, or formed in a waveguide used for optical interconnection, the width 48W of the light absorption layer 48 may be less than a width of the waveguide. For example, when the width of the waveguide is 500 nm or less, the width 48W of the light absorption layer 48 may be 300 nm or less, 200 nm or less, or 100 nm or less, but is not limited to these ranges. In one example, a thickness 48H of the light absorption layer 48 may be designed to be less than a thickness of an apparatus or a member (e.g., waveguide) on which the first photodetector 100 will be mounted. For example, when the waveguide is designed to have a thickness of 500 nm or less, the thickness 48H of the light absorption layer 48 may be less than 500 nm. For example, when the thickness of the waveguide is about 400 nm, the thickness 48H of the light absorption layer 48 may be about 300 nm, but is not limited thereto. The light absorption layer 48 may include the nanostructure 50. The nanostructure 50 may be expressed as a nanopattern or a meta-pattern. The light absorption layer 48 may include a plurality of nanostructures 50 arranged to be spaced apart from each other in a Y-axis direction. The nanostructure 50 may be located between left and right sides of the light absorption layer 48 in a horizontal direction (e.g., X-axis direction), and between upper and bottom (lower) surfaces of the light absorption layer 48 in a vertical direction (e.g., Z-axis direction).

In one example, the nanostructure 50 may be spaced apart from the left and right sides of light absorption layer 48. The nanostructure 50 may be arranged such that a gap between the nanostructure 50 and the left side of light absorption layer 48 is equal to or substantially equal to a gap between the nanostructure 50 and the right side of light absorption layer 48. For example, a horizontal center of the nanostructure 50 may be arranged to coincide or substantially coincide with a horizontal center of the light absorption layer 48. In one example, the nanostructure 50 may be arranged to be spaced apart from the upper and lower surfaces of the light absorption layer 48, and gaps between the nanostructure 50 and the upper and lower surfaces of the light absorption layer 48 may be the same or substantially the same. For example, a vertical center of the nanostructure 50 may be formed to coincide or substantially coincide with a vertical center of the light absorption layer 48.

A vertical thickness of the nanostructure 50 may be less than the thickness 48H of the light absorption layer 48 and less than a wavelength of light (e.g., infrared rays) incident on the light absorption layer 48. A width of the nanostructure 50 in the horizontal direction may be less than the width 48W of the light absorption layer 48 and may be less than the wavelength of light (e.g., infrared rays) incident on the light absorption layer 48. In one example, the width and thickness of the nanostructure 50 may be the same or different from each other. For example, the width of the nanostructure 50 may be greater than the thickness of the nanostructure 50. In one example, the nanostructure 50 may include a metal that is configured to generate a plasmon effect or plasmonic effect at an interface with the light absorption layer 48. As an example, the nanostructure 50 may include a gold nanostructure including gold (Au), a silver nanostructure including silver (Ag), or an aluminum nanostructure including aluminum (Al), but the metals are not limited thereto.

A first groove 40G exists between the first doped layer 42 and the second doped layer 44 in the substrate 40, and the first groove 40G is filled with the light absorption layer 48. A depth of the first groove 40G may be the same or substantially the same as a depth of the first and second doped layers 42 and 44.

The first doped layer 42 and the second doped layer 44 are provided to face each other and to be spaced apart from each other with the light absorption layer 48 therebetween. Horizontal widths of the first and second doped layers 42 and 44 may be the same or substantially the same from each other, and may be in direct contact with the light absorption layer 48.

In one example, the first and second doped layers 42 and 44 may be regions doped with an n-type impurity. The doping type or doping structure of the first and second doped layers 42 and 44 may be the same or substantially the same from each other, but may not be the same. In one example, the first doped layer 42 may have an n+n++ type doping structure in a direction away from the light absorption layer 48. A doping structure of the second doped layer 44 may be symmetrical to that of the first doped layer 42. For example, the second doped layer 44 may have an n+n++ doped structure in a direction away from the light absorption layer 48. Here, the n+n++ type doping structure may denote that the doping concentration increases in the direction away from the light absorption layer 48.

An interlayer insulating layer 52 may be formed on the substrate 40. The interlayer insulating layer 52 may be provided to cover the first and second doped layers 42 and 44 and the light absorption layer 48. The interlayer insulating layer 52 may include a first via hole 52V1 and a second via hole 52V2 that penetrate the interlayer insulating layer 52 and are spaced apart from each other. The first doped layer 42 may be exposed through the first via hole 52V1, and the second doped layer 44 may be exposed through the second via hole 52V2. The interlayer insulating layer 52 may include, but is not limited to, a silicon oxide (e.g., SiO₂) layer. A first electrode layer 54, a second electrode 56, and a third electrode layer 58 spaced apart from each other are provided on the interlayer insulating layer 52. The first electrode layer 54 fills the first via hole 52V1 and is in contact with the first doped layer 42. The second electrode layer 56 fills the second via hole 52V2 and is in contact with the second doped layer 44. The third electrode layer 58 is provided between the first electrode layer 54 and the second electrode layer 56. The third electrode layer 58 may be provided directly above the light absorption layer 48 and may be provided to face the light absorption layer 48 with the interlayer insulating layer 52 therebetween. The third electrode layer 58 may be an electrode that controls the flow of photocurrent generated in the light absorption layer 48 by a photoelectric effect, and may be referred to as a gate electrode. Therefore, the first photodetector 100 may be said to be a transistor (Tr) type photodetector.

In one example, the electrode layer 54, the second electrode 56, and the third electrode layer 58 may include the same conductive material, but the conductive material of one or more electrode layers of the electrode layer 54, the second electrode 56, and the third electrode layer 58 may be different from the conductive material of the remaining electrode layers of the electrode layer 54, the second electrode 56, and the third electrode layer 58. In one example, heights of the first electrode layer 54, the second electrode layer 56, and the third electrode layer 58 may be the same from each other, but may also be different. For example, the height of the third electrode layer 58 may be different from the height of the first and second electrode layers 54 and 56.

In one example, the nanostructure 50 may be divided into two nanostructures 50a and 50b that are at the same position in the vertical direction and are spaced apart from each other in the horizontal direction (e.g., X-axis direction), as illustrated in FIG. 2. In other words, in a first photodetector 100′ of FIG. 2, two nanostructures 50a and 50b spaced apart from each other in the horizontal direction may be disposed in the light absorption layer 48.

When light incident on the light absorption layer 48 has two modes, the first nanostructure 50a and the second nanostructure 50b of FIG. 2 may be used to correspond to each mode. For example, the first nanostructure 50a may be provided to match a period of a first mode of incident light, and the second nanostructure 50b may be provided to match a period of a second mode of incident light.

In one example, when light incident on the light absorption layer 48 has three modes, the light absorption layer 48 may be provided with three nanostructures spaced apart from each other in the horizontal direction. That is, nanostructures spaced apart from each other in the horizontal direction may be arranged in the light absorption layer 48 in proportion to the number of modes of light incident on the light absorption layer 48.

In one example, the first and second electrode layers 54 and 56 may directly contact the light absorption layer 48 without passing through the first and second doped layers 42 and 44.

FIG. 3 shows an example of this structure.

Referring to FIG. 3, in a first photodetector 100″ of FIG. 3, the light absorption layer 48 may extend below the first and second electrode layers 54 and 56. Accordingly, the light absorption layer 48 may be exposed through the first and second via holes 52V1 and 52V2. The first electrode layer 54 may be in direct contact with the light absorption layer 48 while filling the first via hole 52V1, and the second electrode layer 56 may be in direct contact with the light absorption layer 48 while filling the second via hole 52V2.

Based on the example of FIG. 3, the nanostructure 50 may be divided into first and second nanostructures 50a and 50b that are spaced apart from each other in the horizontal direction, as illustrated in FIG. 4. In other words, the light absorption layer 48 in FIG. 3 may include first and second nanostructures 50a and 50b spaced apart from each other in the horizontal direction, as illustrated in FIG. 4.

As described with reference to FIG. 2, the number of nanostructures arranged in the horizontal direction in the light absorption layer 48 may vary in proportion to the number of modes of light incident on the light absorption layer 48.

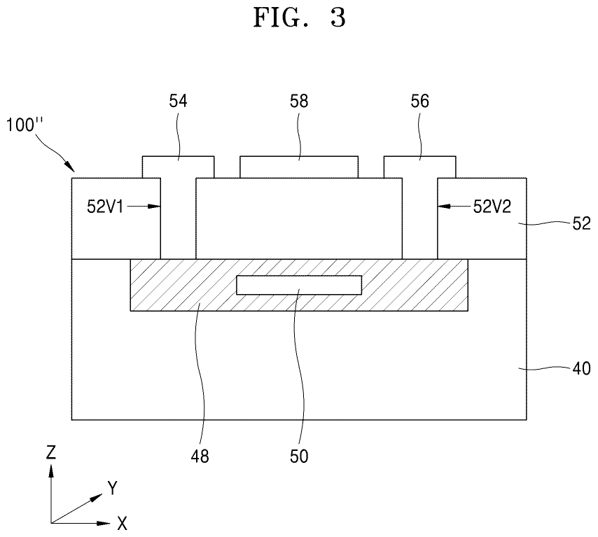

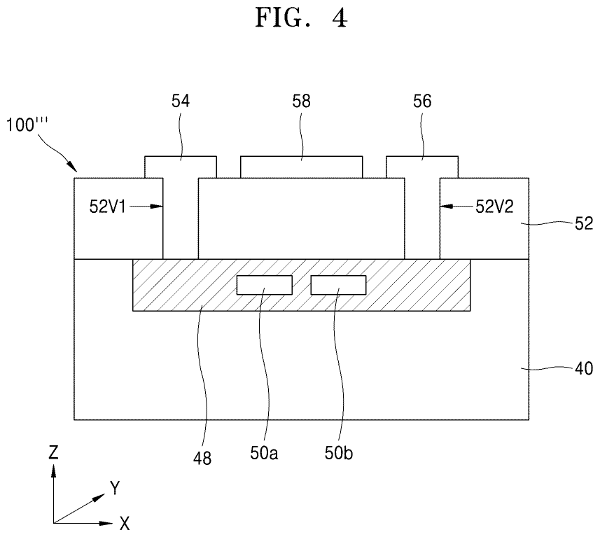

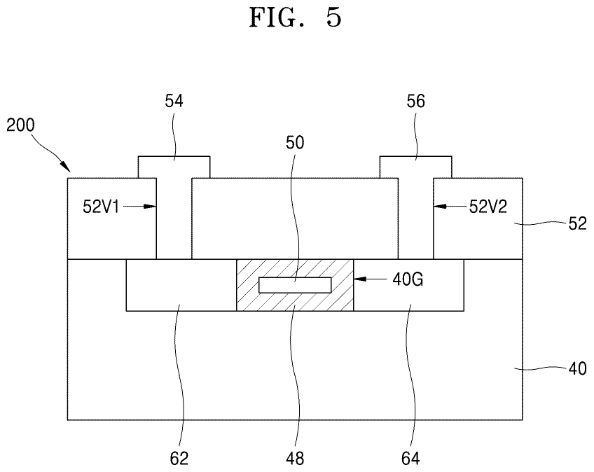

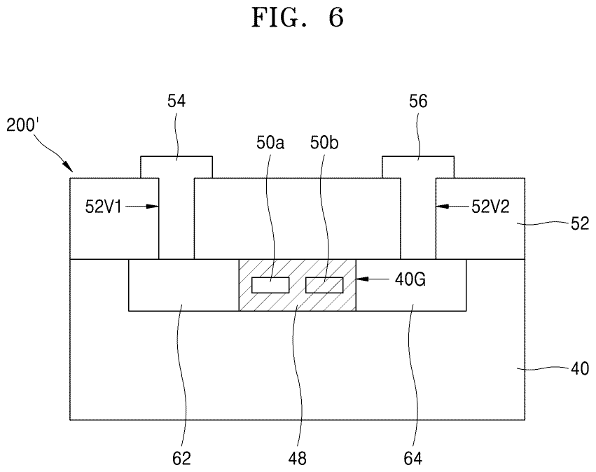

FIG. 5 and FIG. 6 are cross-sectional views showing a second photodetector according to one or more example embodiments. FIG. 5 shows a second photodetector 200 according to an example embodiment. Only parts that are different from the first photodetector 100 of FIG. 1 will be described, and like reference numerals as those mentioned in the description of the first photodetector 100 indicate like members.

Referring to FIG. 5, the second photodetector 200 includes a third doped layer 62 in the location of the first doped layer 42 of the first photodetector 100 and a fourth doped layer 64 in the location of the second doped layer 44 of the first photodetector 100. In one example, the third doped layer 62 may be a region doped with a p-type or n-type impurity, and the fourth doped layer 64 may also be a region doped with a p-type or n-type impurity. For example, the third doped layer 62 may be a p-type doped region, and the fourth doped layer 64 may be an n-type doped region, and vice versa.

The second photodetector 200 may not have an electrode layer corresponding to the third electrode layer 58 of the first photodetector 100. That is, the second photodetector 200 may include only the first and second electrode layers 54 and 56. The first electrode layer 54 may contact the third doped layer 62 through the first via hole 52V1, and the second electrode layer 56 may contact the fourth doped layer 64 through the second via hole 52V2. When a photocurrent is generated from the light absorption layer 48 in the second photodetector 200, depending on the doping types of the third and fourth doped layers 62 and 64, the photocurrent may flow from the third doped layer 62 to the fourth doped layer 64 or vice versa. Therefore, the second photodetector 200 may be referred to as a photodiode (PD) type photodetector.

In one example, the nanostructure 50 of FIG. 5 may be divided into two nanostructures 50a and 50b spaced apart from each other in the horizontal direction, as illustrated in FIG. 6. In other words, in the second photodetector 200′ of FIG. 6, two nanostructures spaced apart from each other in the horizontal direction may be disposed within the light absorption layer 48.

As described with reference to FIG. 2, the number of nanostructures arranged to be spaced apart from each other in the horizontal direction in the light absorption layer 48 may be proportional to the number of modes of light incident on the light absorption layer 48. For example, when the number of modes of light incident on the light absorption layer 48 of the second photodetector 200 of FIG. 5 is three, the light absorption layer 48 may include three nanostructures spaced apart from each other in the horizontal direction.

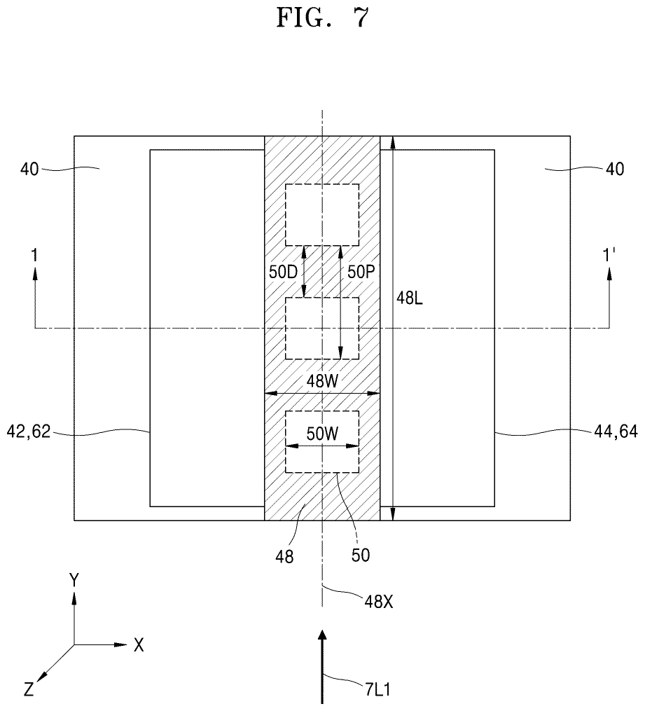

FIG. 7 is a plan view of the first photodetector 100 of FIG. 1 and the second photodetector 200 of FIG. 5. For convenience of explanation, in the first and second photodetectors 100 and 200 of FIGS. 1 and 5, the interlayer insulating layer 52 and the first to third electrode layers 54, 56, and 58 formed on the interlayer insulating layer 52 are excluded. Excluding the first to third electrode layers 54, 56, and 58, FIGS. 1 and 5 may be considered as cross-sectional views taken along line 1-1′ of FIG. 7.

Referring to FIG. 7, the plurality of nanostructures 50 are aligned in a longitudinal direction (e.g., Y-axis direction) of the light absorption layer 48 and aligned on a central axis 48X of the longitudinal direction of the light absorption layer 48. The plurality of nanostructures 50 are aligned at a first pitch 50P, and a spacing 50D between the plurality of nanostructures 50 may be constant or substantially constant. The first pitch 50P and the spacing 50D may be determined in consideration of a mode period of light 7L1 incident on the light absorption layer 48. For example, the first pitch 50P of the plurality of nanostructures 50 may be the same or substantially the same as the mode period of the light 7L1 incident on the light absorption layer 48. Accordingly, the mode of light 7L1 incident on the light absorption layer 48 may be maintained even within the light absorption layer 48.

A horizontal width 50W of the plurality of nanostructures 50 may be less than the width 48W in the horizontal direction of the light absorption layer 48. In one example, a width of the plurality of nanostructures 50 in the longitudinal direction of the light absorption layer 48 may be the same as or different from the horizontal width 50W of the plurality of nanostructures 50. In one example, the horizontal width 50W of the plurality of nanostructures 50 may be less than a wavelength of the incident light 7L1. In one example, a length 48L of the light absorption layer 48 may be 1 μm or less, but is not limited thereto. The length 48L of the light absorption layer 48 may be substantially a length of the first photodetector 100 and/or a length of the second photodetector 200. The first doped layers 42 and 62 may be disposed parallel to the light absorption layer 48 in the longitudinal direction of the light absorption layer 48. The second doped layers 44 and 64 may also be arranged parallel to the light absorption layer 48 in the longitudinal direction of the light absorption layer 48. The first doped layers 42 and 62 and the second doped layers 44 and 64 may be provided to be symmetrical to each other with the light absorption layer 48 therebetween. Lengths of the first doped layers 42 and 62 and the second doped layers 44 and 64 in the longitudinal direction of the light absorption layer 48 may be less than the length 48L of the light absorption layer 48.

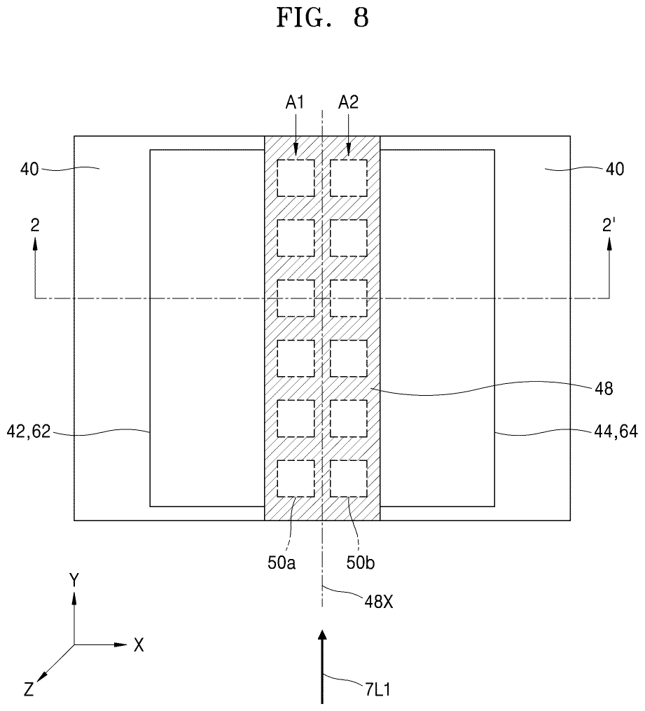

FIG. 8 is a plan view of the first photodetector 100′ of FIG. 2 and the second photodetector 200′ of FIG. 6. For convenience of explanation, in the first and second photodetectors 100′ and 200′ of FIGS. 2 and 6, the interlayer insulating layer 52 and the first to third electrode layers 54, 56, and 58 formed on the interlayer insulating layer 52 are excluded. Excluding the first to third electrode layers 54, 56, and 58, FIGS. 2 and 6 may be considered as cross-sectional views taken along line 2-2′ of FIG. 8.

Referring to FIG. 8, the light absorption layer 48 includes a plurality of first nanostructures 50a in a first row A1 and a plurality of second nanostructures 50b in a second row A2 that are aligned in a row in the longitudinal direction of the light absorption layer 48. The first and second nanostructures 50a and 50b in the first and second rows A1 and A2 may be arranged parallel to each other.

In one example, a size of the first nanostructures 50a may be the same or substantially the same as a size of the second nanostructures 50b. In one example, the plurality of first nanostructures 50a may be aligned at substantially constant intervals in the first row A1. In the second row A2, the plurality of second nanostructures 50b may be aligned at substantially constant intervals. In one example, an alignment spacing of the plurality of first nanostructures 50a in the first row A1 may be the same or substantially the same as an alignment spacing of the plurality of second nanostructures 50b in the second row A2, but it may not be so. In one example, when the light incident on the light absorption layer 48 includes two modes (first and second modes), the alignment spacing of the plurality of first nanostructures 50a in the first row A1 may be the same or substantially the same as a period of the first mode. Additionally, an alignment spacing of the plurality of second nanostructures 50b in the second row A2 may be equal to or substantially equal to a period of the second mode.

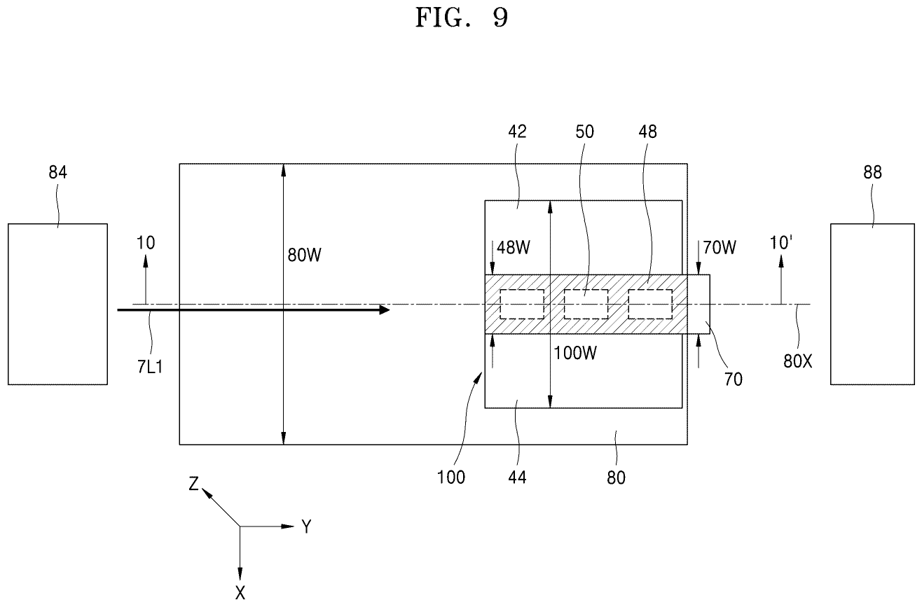

FIG. 9 shows a case when the first photodetector 100 is coupled to a waveguide 80 as a device (system) for optical interconnection according to an example embodiment. In one example, the first photodetector 100 may be replaced with the first photodetector 100″ shown in FIG. 3 or the second photodetector 200 shown in FIG. 5. In addition, depending on the number of modes of incident light, the first photodetector 100 may be replaced with the first photodetector 100′ shown in FIG. 2 or the first photodetector 100″ shown in FIG. 4 or the second photodetector 200′ shown in FIG. 6.

Referring to FIG. 9, the first photodetector 100 may be provided at one end (or end portion) of the waveguide 80. The waveguide 80 may have a central axis 80X in the longitudinal direction (e.g., Y-axis direction). The first photodetector 100 may be provided on the central axis 80X of the waveguide 80, and the central axis of the first photodetector 100, that is, the central axis 48X of the light absorption layer 48 may be provided to coincide with the central axis 80X of the waveguide 80. In one example, the first photodetector 100 may be provided on the central axis 80X of the waveguide 80 such that a right end of the light absorption layer 48 coincides with a right end of the waveguide 80. A width 80W of the waveguide 80 in a direction perpendicular to the longitudinal direction (e.g., a direction parallel to the X-axis) may be greater than a width 100W of the first photodetector 100. In one example, the width 80W of the waveguide 80 may be substantially equal to the width 100W of the first photodetector 100. In this case, in the first photodetector 100, the width 48W of the light absorption layer 48 may be maintained as is, and widths of the first and second doped layers 42 and 44 may be expanded. For example, in FIG. 1, an upper surface of the first doped layer 42 may be extended to an upper surface of the waveguide 80, and a lower surface of the second doped layer 44 may be extended to a lower surface of the waveguide 80.

A light reflection layer 70 may be provided at a right end portion of the light absorption layer 48 of the first photodetector 100. The light reflection layer 70 may be expressed as a light reflector, a light reflection member, a reflective layer, etc. A width 70W of the light reflection layer 70 may be the same or substantially the same as the width 48W of the light absorption layer 48. In one example, the width 70W of the light reflecting layer 70 may be greater than the width 48W of the light absorption layer 48. Accordingly, an entire right side surface of the light absorption layer 48 may be covered with the light reflection layer 70. In one example, the light reflection layer 70 may be in direct contact with the light absorption layer 48. The light reflection layer 70 may be spaced apart from the first and second doped layers 42 and 44. The light reflection layer 70 and the nanostructure 50 may also be spaced apart from each other. In one example, the light reflection layer 70 and the nanostructure 50 may be spaced apart from each other at a distance that a mode of light incident on the light absorption layer 48 may be maintained within the light absorption layer 48 even after the light incident on the light absorption layer 48 is reflected by the light reflection layer 70. As the light reflection layer 70 is provided, light incident on the light reflection layer 70 through the light absorption layer 48 may return to the light absorption layer 48, and thus, a time the light incident on the light absorption layer 48 stays in the light absorption layer 48 may be increased. As a result, a light trapping time of the light absorption layer 48 may be increased and this may lead to increase the light absorption rate.

In one example, a gap between the light reflection layer 70 and the nanostructure 50 adjacent thereto may be less than or equal to a first pitch 50P of the nanostructure 50. In one example, the light reflection layer 70 may be a metal reflection layer. As an example, the light reflection layer 70 may be a reflection layer including gold or may include a gold reflection layer, but is not limited thereto. In one example, instead of the light reflection layer 70, a case when a reflection layer such as DBR is provided between the right side of the light absorption layer 48 and the nanostructure 50 adjacent thereto may be considered.

Light 7L1 incident on the waveguide 80 from a left side of the waveguide 80 may include an optical signal emitted from a first optical device 84 provided on the left side of the waveguide 80. The first optical device 84 may include an electro-optical conversion device that receives an electrical signal and generates an optical signal corresponding to the received electrical signal. A second optical device 88 may be provided on a right side of the waveguide 80, and the second optical device 88 may be a device for converting and outputting an optical signal transmitted through the waveguide 80 and the first photodetector 100 into an electric signal. In one example, the second optical device 88 may include a photoelectric conversion device. In one example, the first optical device 84, the second optical device 88, the waveguide 80, and the first photodetector 100 may be some of elements that constitute a receiving unit (e.g., a receiver or a receiving device) of a communication device.

Because FIG. 9 is a plan view, in order to clearly show the coincidence of the central axis 80X of the waveguide 80 and the central axis 48X of the light absorption layer 48 of the first photodetector 100, members formed on the light absorption layer 48 of the first photodetector 100, that is, the interlayer insulating layer 52 and the first to third electrode layers 54, 56, and 58 are not shown. In addition, except for a surface of the waveguide 80 where the light 7L1 is incident, a peripheral side and a lower surface of the waveguide 80 may be covered with an insulating material (e.g., SiO₂) having a refractive index different from that of the waveguide 80 to prevent light leakage, but is not shown in FIG. 9 for convenience.

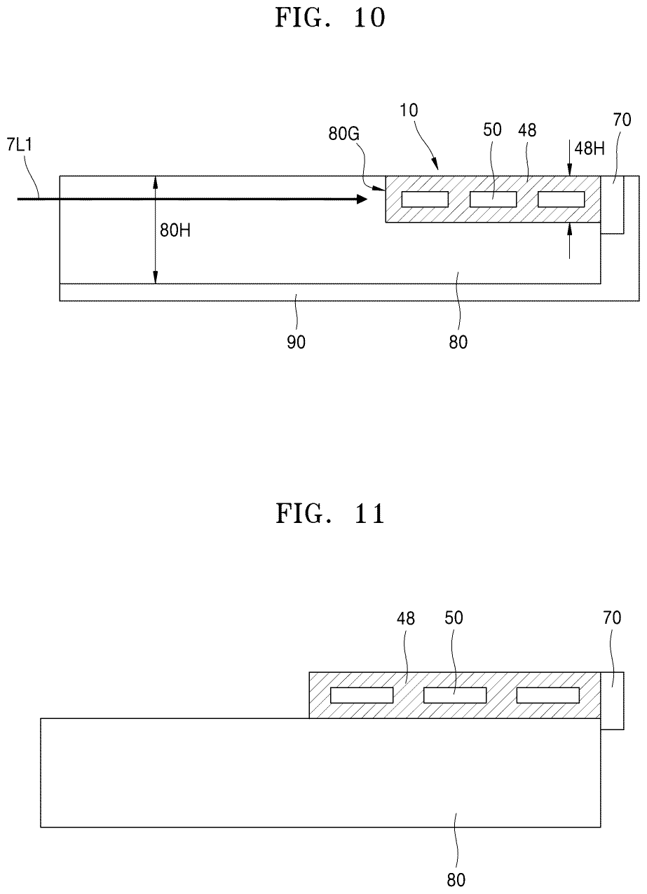

FIG. 10 is a cross-sectional view taken along line 10-10′ of FIG. 9. FIG. 11 is a cross-sectional view showing a case where a light absorption layer is provided on an upper surface of the waveguide in FIG. 10.

Referring to FIG. 10, the lower surface of the waveguide 80 may be covered with an insulating layer 90. A front surface of the waveguide 80, on which the light reflection layer 70 is provided, may also be covered with the insulating layer 90. In one example, the insulating layer 90 may be a material layer with a refractive index different from that of the waveguide 80 and may include a silicon oxide layer, but is not limited thereto. The thickness 48H of the light absorption layer 48 may be less than the thickness 80H of the waveguide 80. The light absorption layer 48 may be spaced apart from the lower surface of the waveguide 80. A groove 80G may be formed in the waveguide 80. The groove 80G may have a shape in which one side (e.g., right side) is open. The groove 80G may be expressed as a recess portion or a recess region of the waveguide 80. The groove 80G may be filled with the light absorption layer 48, and the nanostructures 50 may be embedded within the light absorption layer 48. A height of the light absorption layer 48 may be sufficient to completely fill the groove 80G. An upper surface of the light absorption layer 48 may be flat, and a height of the upper surface of the light absorption layer 48 may be the same as the height of the upper surface of the waveguide 80 adjacent to the groove 80G. Accordingly, the upper surface of the light absorption layer 48 and the upper surface of the waveguide 80 may form the same plane.

In one example, the waveguide 80 may not include the groove 80G, and the light absorption layer 48 may be provided on the upper surface of the waveguide 80 as shown in FIG. 11. The light reflection layer 70 may be provided to completely cover the right side of the light absorption layer 48. In one example, in FIGS. 10 and 11, the light reflection layer 70 may be provided to cover a portion of the side surface of the waveguide 80 below the light absorption layer 48. In one example, in the case of FIG. 11, a length of the light absorption layer 48 may be greater than that of the light absorption layer 48 in the case of FIG. 10, and in this case, the light reflection layer 70 may be omitted.

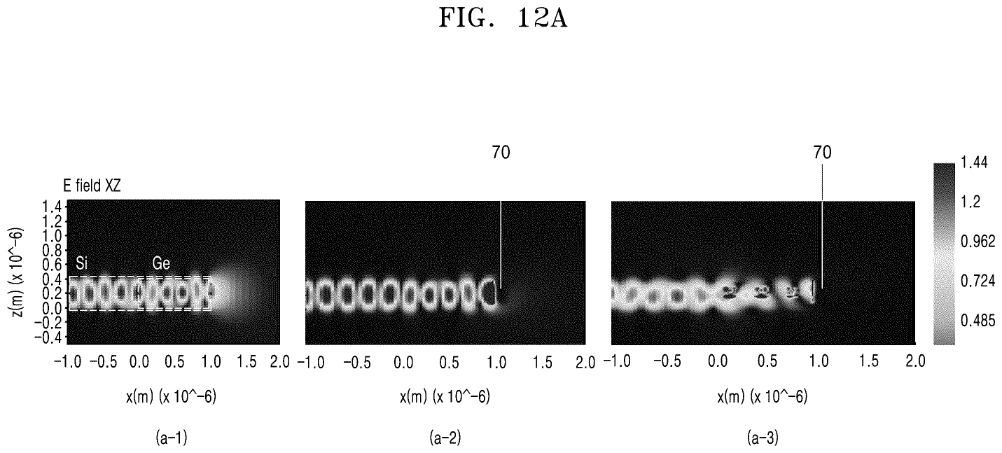

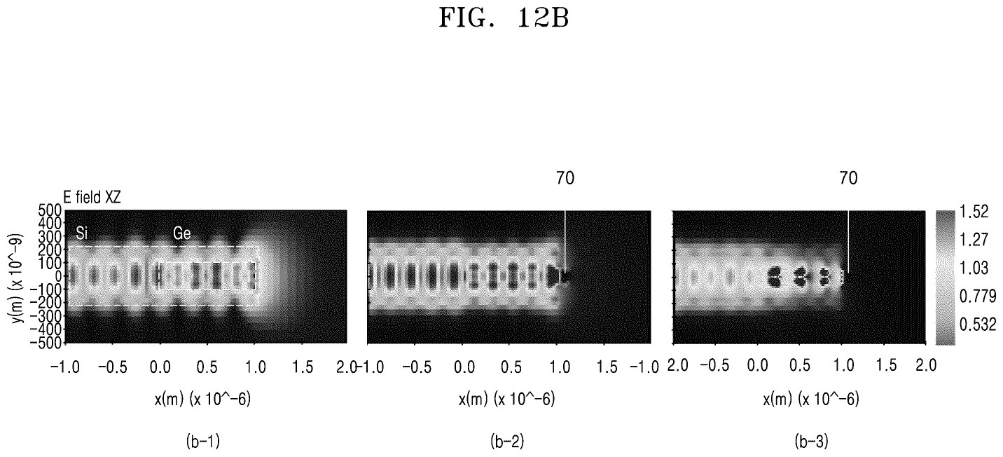

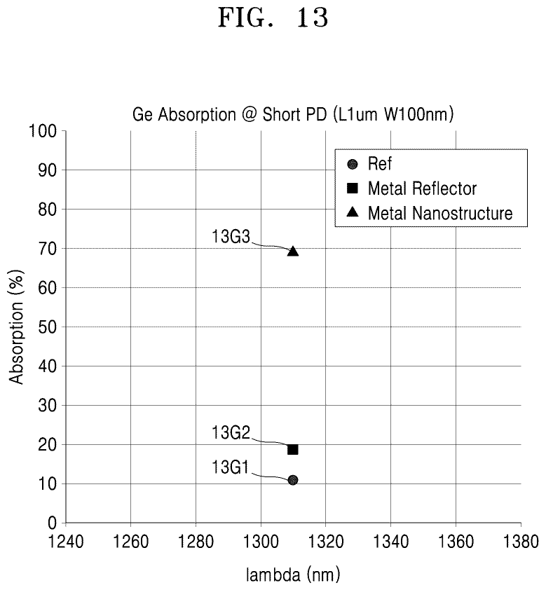

Next, a simulation performed to examine optical characteristics (e.g., light absorption characteristics) for a case when the first photodetector 100 is coupled to the waveguide 80 as shown in FIGS. 9 and 10, and the results are explained with reference to FIGS. 12A, 12B, and 13.

In the simulation, the thickness 80H of the optical waveguide 80 was set to 400 nm and the width 80W was set to 400 nm, and the thickness 48H of the light absorption layer 48 of the first photodetector 100 was set to 300 nm and the width 48W was set to 100 nm. Also, a distance between the light absorption layer 48 and the lower surface of the waveguide 80 was set to 100 nm. Also, the waveguide 80 was set to be a silicon waveguide including silicon, and the light absorption layer 48 was set to be a Ge layer. Additionally, a length of the light absorption layer 48 was set to 1 μm, and a length of the waveguide 80 was set to be greater than the light absorption layer 48. In addition, the waveguide 80 and the light absorption layer 48 were set to be coupled by Butt coupling so that their central axes in the longitudinal direction coincided with each other. Also, the nanostructure 50 was set as a gold (Au) nanostructure. Also, the light reflection layer 70 was set as a gold reflection layer including gold. Also, light incident on the waveguide 80 is light belonging to the infrared band, and is set to be short wave infrared (SWIR) or light used in optical communication.

First to third samples were used in the simulation. The first sample is a case in which the nanostructure 50 is not embedded in the light absorption layer 48 and the light reflection layer 70 is not present, which may correspond to a case when the first photodetector 100 does not include the nanostructure 50 and the light reflection layer 70. The second sample is a case when the nanostructure 50 is included but the light reflection layer 70 is not included, which may correspond to a case when the first photodetector 100 does not include the light reflection layer 70. The third sample is a case when both the nanostructure 50 and the light reflection layer 70 are included, which may correspond to the first photodetector 100.

FIGS. 12A and 12B show an electric field distribution in the light absorption layer 48 when light with a wavelength of 1310 nm is incident on the first to third samples in the simulation.

FIG. 12A shows the electric field distribution measured in side surfaces of the first to third samples (e.g., the cross section corresponding to FIG. 10), and FIG. 12B shows the electric field distribution measured in planes of the first to third samples (e.g., the plane corresponding to FIG. 9).

In FIG. 12A, (a-1) is for the first sample, (a-2) is for the second sample, and (a-3) is for the third sample. In FIG. 12B, (b-1) is for the first sample, (b-2) is for the second sample, and (b-3) is for the third sample. In FIGS. 12A and 12B, the darker the red color, the higher the electric field intensity is.

Referring to FIGS. 12A and 12B, the electric field is formed in the waveguide 80 (“Si”) and is transmitted to the light absorption layer 48 (“Ge”), but because the width 48W of the light absorption layer 48 is less than the width 80W of the waveguide 80, an electric field mode is slightly contracted. However, it can be seen that most of the energy is distributed on the central axis and is transmitted to the light absorption layer 48.

However, in the case of the first sample ((a-1), (b-1)) in which the nanostructure 50 and the light reflection layer 70 are not included, the strength of the electric field is weak compared to other samples, and the electric field is diverged at the end of the light absorption layer 48 (“Ge”).

In the case of the second sample ((a-2), (b-2)), because the light reflection layer 70 is provided at the end of the light absorption layer 48, light incident on the light absorption layer 48 and traveling along the light absorption layer 48 is reflected back into the light absorption layer 48 by the light reflection layer 70. Accordingly, the time that the light incident on the light absorption layer 48 stays in the light absorption layer 48 increases compared to when the light reflection layer 70 is not present, and as a result, the light absorption rate of the light absorption layer 48 may increase. Numerically, in the case of the second sample, the light absorption rate increases by about twice that of the first sample, which will be described later.

In the case of the third samples ((a-3, b-3)), because the metal nanostructures 50 are distributed at the center of the light absorption layer 48 so as to match the mode period of the incident light, a plasmonic effect occurs between the metal and the light absorption layer 48, which is a dielectric material. This induces a rapid field enhancement, or concentration of the electric field. Also, an electric field change occurs between the light reflection layer 70 and the nanostructure 50. Accordingly, damage (breaking) of an optical signal mode transmitted to the light absorption layer 48 may be minimized and, even though the length of the light absorption layer 48 is less than that of an existing light detector, the light absorption rate may be increased.

FIG. 13 shows a light absorption rate-wavelength relationship for the first to third samples as one of the results of the simulation described with reference to FIGS. 12A and 12B.

In FIG. 13, a horizontal axis represents a wavelength of incident light and a vertical axis represents a light absorption rate. In FIG. 13, reference numeral 13G1 represents the light absorption rate of the first sample when the wavelength of incident light is 1310 nm, reference numeral 13G2 represents the light absorption rate of the second sample when the wavelength of incident light is 1310 nm, and reference numeral 13G3 represents the light absorption rate of the third sample when the wavelength of incident light is 1310 nm.

Referring to FIG. 13, the light absorption rate of the first sample is about 10%, while the light absorption rate of the second sample is about 20%, which is about twice greater than that of the first sample. The light absorption rate of the third sample is about 70%, which is about 7 times greater than the light absorption rate of the first sample.

The results of FIG. 13 show that even when the length of the light absorption layer 48 is less than 1 μm, which is less than that of the existing photodetector, the light absorption rate may be increased when the light reflection layer 70 is provided at the end of the light absorption layer 48, and shows that when the nanostructure 50 is embedded in the center (or center portion) of the light absorption layer 48 in addition to the light reflector layer 70, the light absorption rate may further be increased.

The results of FIGS. 12 and 13 suggest that, like the photodetector according to an example embodiment described above, when a nanostructure is embedded in the center of the light absorption layer and a light reflection layer is provided at the end of the light absorption layer, the length of the absorption layer may be reduced while preventing the decrease in light absorption rate.

The reduction of the length of the light absorption layer may denote the reduction of the size of the photodetector, and thus, when the photodetector according to an example embodiment is used, the integration degree of the photodetector may be increased by reducing the size of the photodetector, noise such as dark current may also be reduced, and a parasitic impedance that may occur during a high-speed operation may also be reduced.

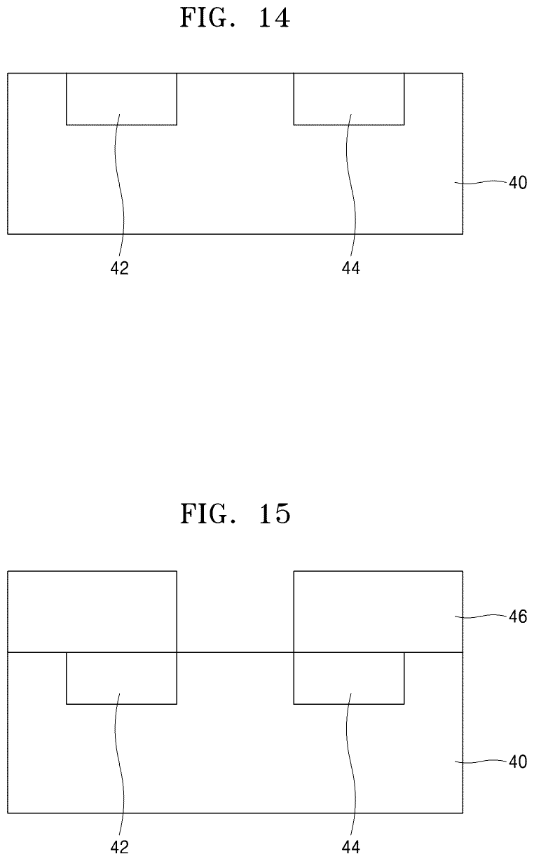

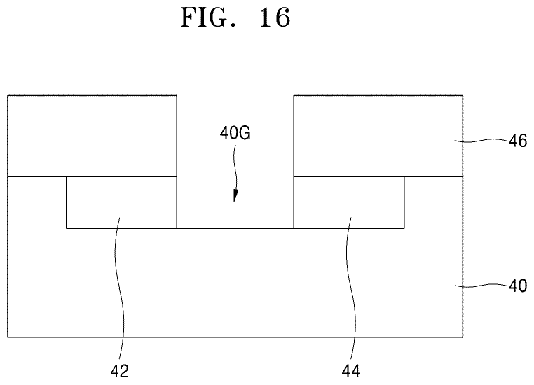

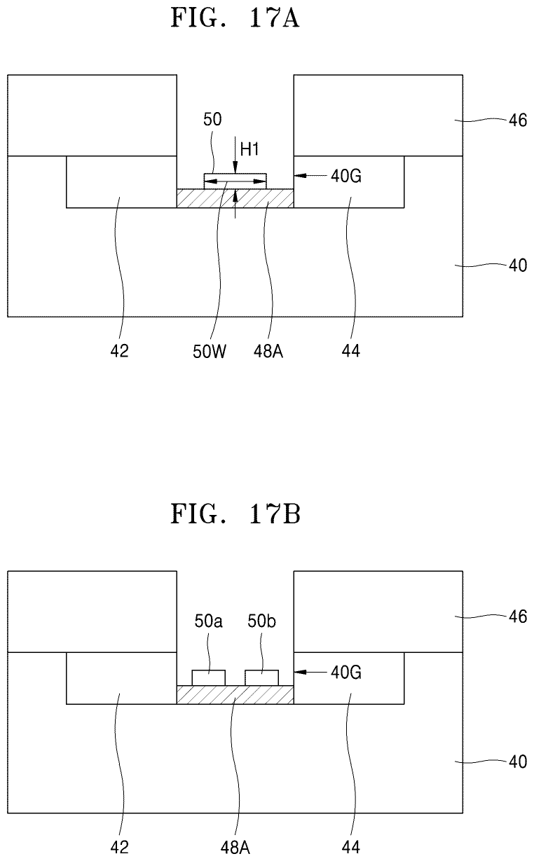

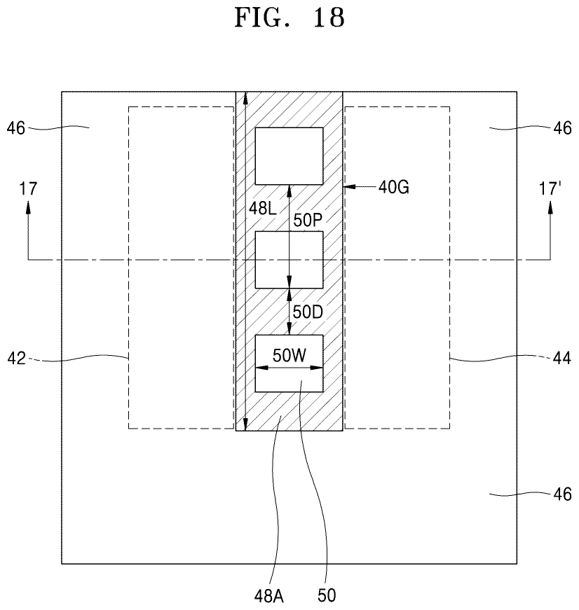

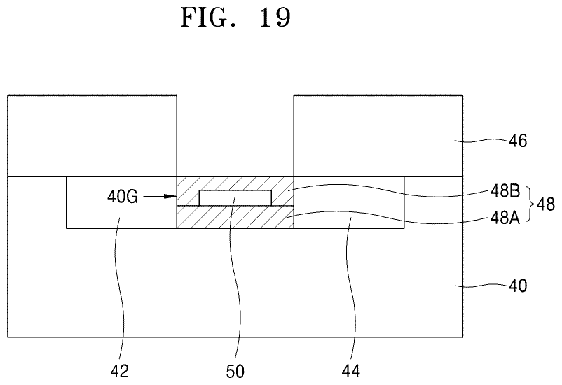

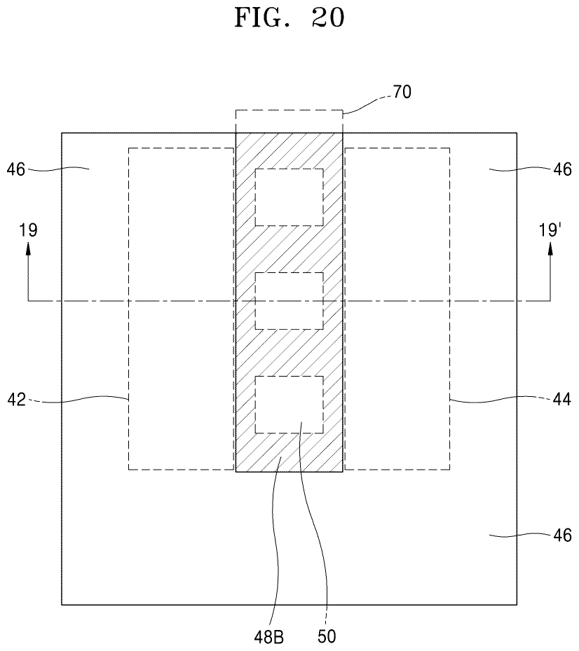

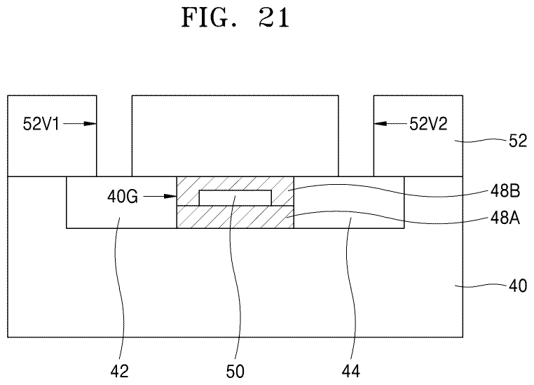

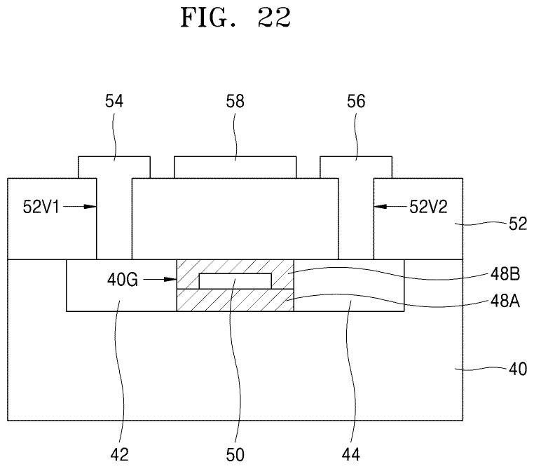

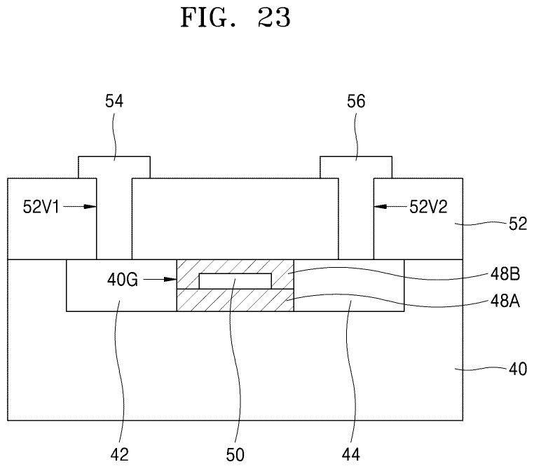

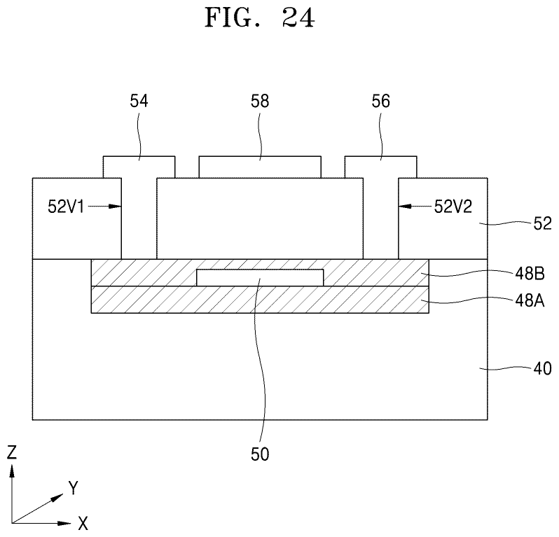

Next, a method of manufacturing a photodetector according to an example embodiment will be described step by step with reference to FIGS. 14 to 24. In the description of the manufacturing method below, the same reference numerals as those mentioned in the photodetector described above indicate the same members, and description thereof will be omitted.

Referring to FIG. 14, first and second doped layers 42 and 44 to be spaced apart from each other may be formed on a substrate 40. Because a light absorption layer is to be formed between the first doped layer 42 and the second doped layer 44 in a subsequent process, a separation distance between the first doped layer 42 and the second doped layer 44 may be determined taking this aspect into account. Doping depths of the first and second doped layers 42 and 44 may be the same or substantially the same.

Next, as shown in FIG. 15, an interlayer insulating layer 46 may be formed on the substrate 40. The interlayer insulating layer 46 may be formed to cover the first and second doped layers 42 and 44 and to expose the substrate 40 between the first and second doped layers 42 and 44. The interlayer insulating layer 46 may include, but is not limited to, a silicon oxide layer. The interlayer insulating layer 46 may be used as a mask in an etching or material deposition process. Therefore, any material layer that may be used in the etching or deposition process may be used as the interlayer insulating layer 46. In one example, interlayer insulating layer 46 may include a photomask.

Next, as shown in FIG. 16, the substrate 40 between the first doped layer 42 and the second doped layer 44 may be etched to form a groove 40G between the first and second doped layers 42 and 44. A depth of the groove 40G may be substantially the same as a depth of the first and second doped layers 42 and 44, but may be deeper or shallower than the depth of the first and second doped layers 42 and 44.

Next, as shown in FIG. 17A, a part of the groove 40G may be filled with a first light absorption layer 48A. In one example, a thickness of the first light absorption layer 48A may substantially correspond to half of the depth of the groove 40G. In one example, a crystal state of the first light absorption layer 48A may be crystalline, and the first light absorption layer 48A may be formed by an epitaxy method, but may also be formed by another method. Another part of the substrate 40 may be covered with the interlayer insulating layer 46, and the first light absorption layer 48A may be selectively formed only on a bottom (silicon substrate) of the groove 40G between the first and second doped layers 42 and 44. In one example, the first light absorption layer 48A may include the same material as the light absorption layer 48 described with reference to FIG. 1, but is not limited thereto.

After forming the first light absorption layer 48A, the nanostructure 50 may be formed on the first light absorption layer 48A. The nanostructure 50 may be formed such that the center thereof substantially coincides with the center of the first light absorption layer 48A. A thickness H1 of the nanostructure 50 may be less than the depth of the groove 40G and may be the same as or different from the thickness of the first light absorption layer 48A. A width 50W of the nanostructure 50 may be less than a width of the groove 40G and a width of the first light absorption layer 48A.

In one embodiment, a plurality of nanostructures spaced apart from each other in the horizontal direction may be formed on the first light absorption layer 48A. FIG. 17B shows an example of the plurality of nanostructures, in which two nanostructures 50a and 50b that are horizontally spaced apart from each other may be formed on the first light absorption layer 48A. The number of nanostructures formed horizontally on the first light absorption layer 48A may be determined according to the number of modes of incident light. For example, when there is one mode of incident light, only one nanostructure 50 may be horizontally formed as shown in FIG. 17A, and when there are two modes of incident light, two nanostructures 50a and 50b that are horizontally spaced apart from each other may be formed on the first light absorption layer 48A as shown in FIG. 17B. The nanostructure 50 of FIG. 17A and the nanostructures 50a and 50b of FIG. 17B may be formed at positions corresponding to a mode period of incident light.

FIG. 18 is a plan view of FIG. 17A. FIG. 17A may be a cross-sectional view taken along line 17-17′ of FIG. 18.

Referring to FIG. 18, a plurality of nanostructures 50 may be formed on the first light absorption layer 48A in the length direction of the first light absorption layer 48A. The plurality of nanostructures 50 may be aligned in a row. The alignment period (e.g., pitch 50P) of the plurality of nanostructures 50 may be substantially the same as the mode period of incident light.

In one example, the nanostructures 50, 50a, and 50b may be formed by a deposition method, such as a chemical vapor deposition (CVD) method, a physical vapor deposition (PVD) method, an atomic layer deposition (ALD) method, a sputtering method, etc., but the disclosure is not limited thereto.

After forming the nanostructure 50 as shown in FIG. 17A, a second light absorption layer 48B covering the nanostructure 50 may be formed on the first light absorption layer 48A, as shown in FIG. 19. The second light absorption layer 48B may be formed to completely cover the nanostructure 50. The second light absorption layer 48B may be formed to fill a remaining region of the groove 40G after the first light absorption layer 48A and the nanostructure 50 are formed. In one example, the second light absorption layer 48B may be formed until the groove 40G is completely filled. In one example, the second light absorption layer 48B may be formed using the deposition methods described above, but the methods are not limited thereto. In one example, the second light absorption layer 48B may be formed by a different method from a method used to form the first light absorption layer 48A, and thus, the crystalline state of the second light absorption layer 48B may be different from that of the first light absorption layer 48A. For example, the crystalline state of the second light absorption layer 48B may be amorphous. A process for crystallizing the second light absorption layer 48B may be considered in a subsequent process. As the second light absorption layer 48B is formed, the groove 40G may be completely filled with the light absorption layer 48 including the embedded nanostructure 50.

After forming the second light absorption layer 48B, the interlayer insulating layer 46 is removed.

The second light absorption layer 48B may also be formed on an upper surface of the interlayer insulating layer 46, but is not shown in FIG. 19 for convenience of illustration, and in the process of removing the interlayer insulating layer 46, the second light absorption layer 48B formed on the upper surface of the interlayer insulating layer 46 may also be removed.

FIG. 20 is a plan view of FIG. 19. FIG. 19 may be a cross-sectional view taken along line 19-19′ of FIG. 20.

In one example, after the interlayer insulating layer 46 is removed, as shown in FIG. 20, a light reflection layer 70 may be formed at an end of the light absorption layer 48.

In one example, the first and second doped layers 42 and 44 may be formed after forming the second light absorption layer 48B. That is, the light absorption layer 48 and the nanostructure 50 may be formed before the first and second doped layers 42 and 44 are formed.

After the interlayer insulating layer 46 is removed, as shown in FIG. 21, an interlayer insulating layer 52 covering the groove 40G and the second light absorption layer 48B and also covering the first and second doped layers 42 and 44 may be formed on the substrate 40. The interlayer insulating layer 52 may completely cover the groove 40G and the second light absorption layer 48B, and may be in contact with the second light absorption layer 48B. After the interlayer insulating layer 52 is formed, a planarization process may be performed on an upper surface of the interlayer insulating layer 52. As a result, the upper surface of the interlayer insulating layer 52 may be flat. In one example, the planarization process may be performed using a chemical mechanical polishing (CMP) process, but is not limited thereto. After the planarization process, first and second via holes 52V1 and 52V2 spaced apart from each other may be formed in the interlayer insulating layer 52. The first and second via holes 52V1 and 52V2 may be formed on the first and second doped layers 42 and 44, respectively. The first doped layer 42 may be exposed through the first via hole 52V1, and the second doped layer 44 may be exposed through the second via hole 52V2.

Next, as shown in FIG. 22, a first electrode layer 54 filling the first via hole 52V1 and a second electrode layer 56 filling the second via hole 52V2 may be formed on the interlayer insulating layer 52. The first electrode layer 54 may contact the first doped layer 42. The second electrode layer 56 may contact the second doped layer 44. The first and second electrode layers 54 and 56 may be spaced apart from each other. A third electrode layer 58 may be formed on the interlayer insulating layer 52 between the first and second electrode layers 54 and 56. The third electrode layer 58 may be formed at a position spaced apart from the first and second electrode layers 54 and 56. In one example, materials for forming the first to third electrode layers 54, 56, and 58 may be the same, but are not limited thereto. In one example, the first to third electrode layers 54, 56, and 58 may be formed simultaneously using the same deposition method, but the disclosure is not limited thereto. For example, the third electrode layer 58 may be formed after the first and second electrode layers 54 and 56 are formed. In one example, the material of one of the first to third electrode layers 54, 56, and 58 may be different from the others.

The photodetector of FIG. 22 may be a transistor type photodetector.

In one example, after performing up to the operation shown in FIG. 21, only the first electrode layer 54 and the second electrode layer 56 may be formed on the interlayer insulating layer 52, as shown in FIG. 23. In this case, the first doped layer 42 may be a p-type doped region, and the second doped layer 44 may be an n-type doped region. Conversely, the first doped layer 42 may be an n-type doped region, and the second doped layer 44 may be a p-type doped region. The photodetector in FIG. 23 may be a PD type photodetector.

In one example, the light absorption layer 48 in FIG. 22 may extend to the first and second doped layers 42 and 44. That is, as shown in FIG. 24, the first and second light absorption layers 48A and 48B may be formed to extend below the first and second electrode layers 54 and 56, and the first and second electrode layers 54 and 56 may contact the second light absorption layer 48B.

In one example, in the case of FIG. 24, only one nanostructure 50 may be horizontally formed as shown in FIGS. 17A and 17B, or two or more nanostructures 50 that are spaced apart from each other may be formed.

An infrared detector according to an example embodiment may detect infrared rays (SWIR) in a short wavelength band, and a width of the light absorption layer may be narrower than that of an existing infrared detector. Therefore, the operating speed of the infrared detector according to an example embodiment may be faster than that of the existing infrared detector.

In addition, the infrared detector according to an example embodiment may include a metal nanostructure exhibiting a plasmon effect and provided to correspond to a mode period of incident infrared rays inside the light absorption layer. The infrared detector according to an example embodiment may include a light reflection layer at an end of the light absorption layer that reflects light back to the light absorption layer. Accordingly, a time (light trapping time) that light stays in the light absorption layer may be increased, and the light absorption rate may be increased as light is focused on the light absorption layer. Therefore, when the infrared detector according to an example embodiment is used, because a size of the infrared detector may be reduced by reducing a length of the light absorption layer, the integration degree of the infrared detector may be increased, noise such as dark current may be reduced, and a parasitic impedance that may occur in a high-speed operation may also be reduced.

When the infrared detector is applied to a waveguide for optical signal transmission, the transmission speed of an optical signal and the intensity of the optical signal may be increased, and the size of an optical interconnection structure including the waveguide may also be reduced.

It should be understood that example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. An infrared detector comprising:
a substrate;
an infrared absorption layer in contact with the substrate and provided to absorb short-wavelength infrared rays; and
a first electrode layer and a second electrode layer connected to the infrared absorption layer and spaced apart from each other,
wherein the infrared absorption layer comprises a metal nanostructure embedded in a center of the infrared absorption layer and positioned to correspond to a mode period of incident light.

2. The infrared detector of claim 1, wherein the substrate comprises a first doped layer and a second doped layer spaced apart from each other and facing each other with the infrared absorption layer therebetween, and
wherein the first electrode layer is connected to the first doped layer, the second electrode layer is connected to the second doped layer, and the first doped layer and the second doped layer are in contact with the infrared absorption layer.

3. The infrared detector of claim 2, further comprising a third electrode layer provided between the first electrode layer and the second electrode layer,
wherein the third electrode layer is spaced apart from the first electrode layer, the second electrode layer, and the infrared absorption layer.

4. The infrared detector of claim 3, wherein the first doped layer and the second doped layer comprise regions doped with an n-type impurity.

5. The infrared detector of claim 4, wherein, in each of the first doped layer and the second doped layer, a doping concentration increases in a direction away from the infrared absorption layer.

6. The infrared detector of claim 1, further comprising a third electrode layer provided between the first electrode layer and the second electrode layer,
wherein the third electrode layer is spaced apart from the first electrode layer, the second electrode layer, and the infrared absorption layer, and
wherein the first electrode layer and the second electrode layer are in direct contact with the infrared absorption layer.

7. The infrared detector of claim 6, wherein the infrared absorption layer extends below the first and second electrode layers, and the first and second electrode layers are provided on the infrared absorption layer.

8. The infrared detector of claim 2, wherein one of the first doped layer and the second doped layer comprises a region doped with a p-type impurity, and the other of the first doped layer and the second doped layer comprises a region doped with an n-type impurity.

9. The infrared detector of claim 1, wherein the metal nanostructure comprises a plurality of metal nanopatterns arranged in one row, two rows, or three rows in a longitudinal direction of the infrared absorption layer.

10. The infrared detector of claim 9, wherein the plurality of metal nanopatterns are aligned to have a pitch corresponding to the mode period of incident light.

11. The infrared detector of claim 1, wherein the infrared absorption layer has a layer structure in which a crystalline layer and an amorphous layer are sequentially stacked.

12. The infrared detector of claim 1, wherein a length of the infrared absorption layer is 1 μm or less, and a width in a direction perpendicular to a length direction of the infrared absorption layer is 100 nm or less.

13. The infrared detector of claim 1, further comprising a light reflection layer provided at an end portion of the infrared absorption layer.

14. The infrared detector of claim 1, wherein the infrared absorption layer comprises one of a germanium (Ge) layer and a quantum dot layer.

15. An optical interconnection structure comprising:
a waveguide; and
an infrared detector connected to the waveguide,
wherein the infrared detector comprises:
an infrared absorption layer in contact with the waveguide and provided to absorb short-wavelength infrared rays; and
a first electrode layer and a second electrode layer connected to the infrared absorption layer and spaced apart from each other, and
wherein the infrared absorption layer comprises:
a metal nanostructure embedded in a center of the infrared absorption layer and positioned to correspond to a mode period of incident light transmitted through the waveguide; and
a light reflection layer provided at an end portion of the infrared absorption layer.

16. The optical interconnection structure of claim 15, wherein the waveguide comprises a groove, and
wherein the infrared absorption layer is provided to fill the groove.

17. The optical interconnection structure of claim 15, wherein the infrared absorption layer is provided on an upper surface of the waveguide.

18. The optical interconnection structure of claim 16, wherein the waveguide comprises a first doped layer and a second doped layer that are provided to face each other with the infrared absorption layer therebetween, the first doped layer and the second doped layer being spaced apart from each other, and
wherein the first electrode layer is connected to the infrared absorption layer through the first doped layer, and the second electrode layer is connected to the infrared absorption layer through the second doped layer.

19. A method of manufacturing an infrared detector, the method comprising:
forming a first infrared absorption layer by using an epitaxy method in a region of a substrate;
forming a metal nanostructure on the first infrared absorption layer;
forming a second infrared absorption layer on the first infrared absorption layer to completely cover the metal nanostructure; and
forming a first electrode layer and a second electrode layer to be connected to at least the second infrared absorption layer,
wherein the metal nanostructure is positioned corresponding to a mode period of incident light, and
wherein the second infrared absorption layer is formed by using a non-growth method.

20. The method of claim 19, wherein the first electrode layer and the second electrode layer are formed to directly contact the second infrared absorption layer, and
wherein a third electrode layer is formed between the first electrode layer and the second electrode layer to be spaced apart from the first infrared absorption layer and the second infrared absorption layer.
